(19) United States
(12) Patent Application Publication
(10) Pub. No.: US 2025/0185469 A1
(43) Pub. Date: Jun. 5, 2025

(54) DISPLAY PANEL AND METHOD FOR MANUFACTURING THE SAME

(71) Applicant: Samsung Display Co., Ltd., Yongin-si (KR)

(72) Inventor: HYUNEOK SHIN, Yongin-si (KR)

(21) Appl. No.: 18/913,866

(22) Filed: Oct. 11, 2024

(30) Foreign Application Priority Data
Nov. 30, 2023 (KR) 10-2023-0170244

(51) Int. Cl. H10K 59/122; H10K 59/12; H10K 59/80

(52) U.S. Cl. CPC H10K 59/122; H10K 59/1201; H10K 59/80521

(57) ABSTRACT

Provided is a display panel including a base layer, a pixel-defining film above the base layer, and defining a light-emitting opening, a partition wall above the pixel-defining film, defining a partition wall opening corresponding to the light-emitting opening, and including a first partition wall layer including a first conductive material, a partition wall insulation layer above the first partition wall layer, and including an insulation material, and a second partition wall layer above the partition wall insulation layer, and including a second conductive material, and a light-emitting element in the light-emitting opening and the partition wall opening, and including an anode, a light-emitting pattern, and a cathode, the cathode contacting the partition wall.

### CROSS-REFERENCE TO RELATED APPLICATIONS

The present application claims priority to, and the benefit of, Korean Patent Application No. 10-2023-0170244, filed on Nov. 30, 2023, the entire disclosure of which is hereby incorporated by reference.

### BACKGROUND

### 1. Field

The present disclosure herein relates to a display panel with improved display quality, and a method for manufacturing the same.

### 2. Description of the Related Art

Display devices, such as televisions, monitors, smartphones, and tablet computers, which provide users with images, include display panels that display the images. Various display panels, such as liquid crystal display panels, organic light-emitting display panels, electro wetting display panels, and electrophoretic display panels, are developed as display panels.

An organic light-emitting display panel may include an anode, a cathode, and a light-emitting pattern. The light-emitting pattern may be separated for each light-emitting area, and the cathode may supply a common voltage to each light-emitting area.

### SUMMARY

The present disclosure provides a display panel with improved display quality, which provides a light-emitting element without using a metal mask, and a method for manufacturing the display panel.

One or more embodiments of the present disclosure provide a display panel including a base layer, a pixel-defining film above the base layer, and defining a light-emitting opening, a partition wall above the pixel-defining film, defining a partition wall opening corresponding to the light-emitting opening, and including a first partition wall layer including a first conductive material, a partition wall insulation layer above the first partition wall layer, and including an insulation material, and a second partition wall layer above the partition wall insulation layer, and including a second conductive material, and a light-emitting element in the light-emitting opening and the partition wall opening, and including an anode, a light-emitting pattern, and a cathode, the cathode contacting the partition wall.

The partition wall opening may include a first area defined by an inner side surface of the first partition wall layer, and a second area defined by an inner side surface of the partition wall insulation layer, and an inner side surface of the second partition wall layer, wherein a width of the first area in one direction is greater than a width of the second area in the one direction.

The display panel may further include a lower inorganic encapsulation pattern covering the light-emitting element, and spaced apart from a top surface of the partition wall.

A separation area may be defined between the lower inorganic encapsulation pattern and the partition wall, wherein a thickness of the separation area is substantially equal to a thickness of the cathode.

The display panel may further include a cathode dummy layer in a portion of the separation area, and including a same material as the cathode.

The separation area may be empty.

The thickness of the separation area may be about 200 angstrom (Å) or less.

The display panel may further include a capping pattern above the cathode, wherein the thickness of the separation area corresponds to a sum of the thickness of the cathode and a thickness of the capping pattern.

The second partition wall layer may include at least one of titanium (Ti), molybdenum (Mo), or tungsten (W).

The second partition wall layer may include a material having a melting point of about 970 degrees or more.

In one or more embodiments of the present disclosure, a method for manufacturing a display panel includes providing a preliminary display panel including a base layer, and a pixel-defining film above the base layer, forming, on the pixel-defining film, a preliminary partition wall including a first preliminary partition wall layer including a first conductive material, a preliminary partition wall insulation layer including an insulation material, and a second preliminary partition wall layer including a second conductive material, forming a partition wall defining a partition wall opening from the preliminary partition wall, etching the pixel-defining film to form a light-emitting opening overlapping the partition wall opening, forming a light-emitting pattern in the light-emitting opening, and forming a light-emitting pattern dummy layer including a same material as the light-emitting pattern, on the partition wall, and applying heat to the partition wall to remove the light-emitting pattern dummy layer.

The partition wall may include a first partition wall layer including the first conductive material, a partition wall insulation layer above the first partition wall layer, and including the insulation material, and a second partition wall layer above the partition wall insulation layer, and including the second conductive material.

The forming of the partition wall defining the partition wall opening from the preliminary partition wall may include first etching of the first preliminary partition wall layer, the preliminary partition wall insulation layer, and the second preliminary partition wall layer, and second etching of the first preliminary partition wall layer.

The partition wall opening may include a first area defined by an inner side surface of the first partition wall layer, and a second area defined by an inner side surface of the partition wall insulation layer, and by an inner side surface of the second partition wall layer, wherein a width of the first area in one direction is greater than a width of the second area in the one direction.

The applying of the heat to remove the light-emitting pattern dummy layer may include applying a voltage to the second partition wall layer to cause Joule heating.

The method may further include forming a cathode in the light-emitting opening and the partition wall opening, and forming a cathode dummy layer, which includes the same material as the cathode, on the partition wall.

The method may further include forming a lower inorganic encapsulation pattern on the cathode, wherein the cathode dummy layer is between the partition wall and the lower inorganic encapsulation pattern.

The method may further include removing at least a portion of the cathode dummy layer.

The method may further include forming a capping pattern in the partition wall opening, and forming a capping pattern dummy layer, which includes the same material as the capping pattern, on the partition wall.

The forming of the preliminary partition wall may include depositing a second preliminary partition wall layer including a material having a characteristic of a melting point of about 970 degrees or more.

### BRIEF DESCRIPTION OF THE DRAWINGS

The accompanying drawings are included to provide a further understanding of the present disclosure, and are incorporated in, and constitute a part of, this specification. The drawings illustrate embodiments of the present disclosure and, together with the description, serve to explain aspects of the present disclosure. In the drawings:

FIG. 1A is a perspective view of a display device according to one or more embodiments of the present disclosure;

FIG. 1B is an exploded perspective view of a display device according to one or more embodiments of the present disclosure;

FIG. 2 is a cross-sectional view of a display module according to one or more embodiments of the present disclosure;

FIG. 3 is a plan view of a display panel according to one or more embodiments of the present disclosure;

FIG. 4 is an enlarged plan view of a portion of a display area of a display panel according to one or more embodiments of the present disclosure;

FIG. 5A is a cross-sectional view taken along the line I-I′ in FIG. 3;

FIG. 5B is an enlarged view of area AA′ in FIG. 5A;

FIG. 6 is a cross-sectional view taken along the line II-II′ in FIG. 4;

FIGS. 7A to 7L are cross-sectional views illustrating some of operations of a method for manufacturing a display panel according to one or more embodiments of the present disclosure; and

FIG. 8 is a cross-sectional view taken along the line I-I′ in FIG. 3.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

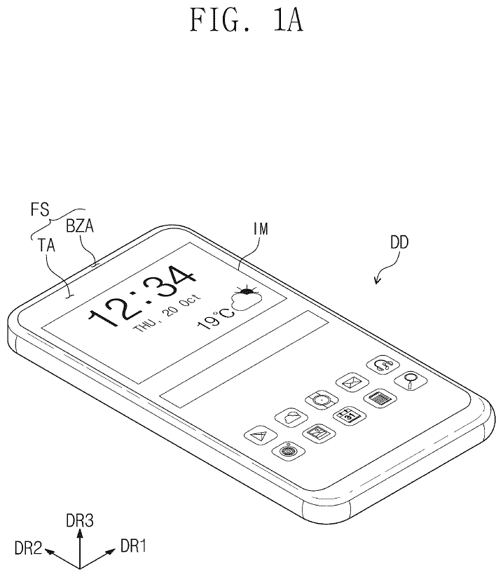

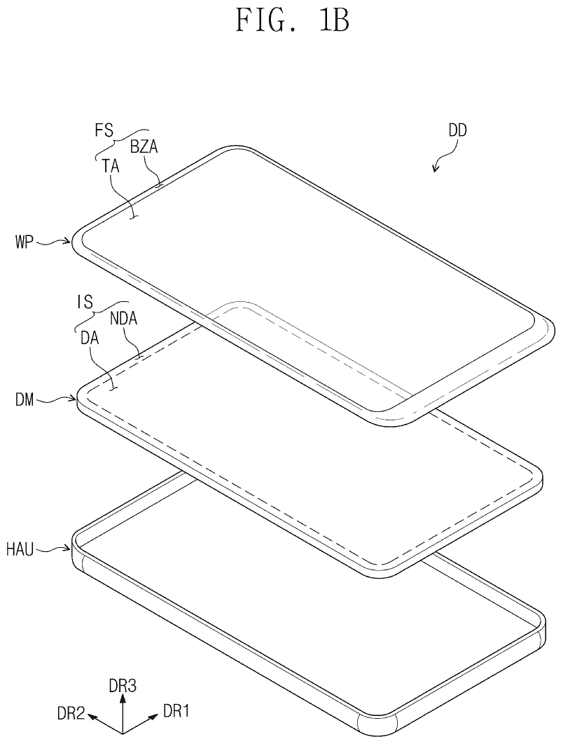

FIG. 1A is a perspective view of a display device DD according to one or more embodiments of the present disclosure. FIG. 1B is an exploded perspective view of the display device DD according to one or more embodiments of the present disclosure.

In one or more embodiments, the display device DD may be a large-sized electronic device, such as a television, a monitor, or an outdoor billboard. In addition, the display device DD may be a small- and medium-sized electronic device, such as a personal computer, a notebook computer, a personal digital assistant, a vehicle navigation unit, a game console, a smartphone, a tablet computer, and a camera. However, the foregoing devices are examples, and the display device DD may also be employed as another display device unless departing from the present disclosure. FIGS. 1A and 1B illustrate a smartphone as an example of the display device DD.

Referring to FIGS. 1A and 1B, the display device DD may display an image IM in a third direction DR3 on a display surface FS parallel to each of a first direction DR1 and a second direction DR2. The image IM may include not only a dynamic image but also a still image. FIG. 1A illustrates a clock window and application icons as an example of the image IM. The display surface FS on which the image IM is displayed may correspond to a front surface of the display device DD.

A front surface (or top surface) and a rear surface (or bottom surface) of each member are defined based on a direction in which the image IM is displayed. The front surface and the rear surface may oppose each other in the third direction DR3, and a normal direction to each of the front surface and the rear surface may be parallel to the third direction DR3. Meanwhile, directions indicated by the first to third directions DR1, DR2 and DR3 are relative concepts and may be changed to other directions. The term “on a plane” used herein may mean a state when viewed in the third direction DR3.

The display device DD may include a window WP, a display module DM, and a housing HAU. The window WP and the housing HAU may be coupled to each other to constitute an outer appearance of the display device DD.

The window WP may include an optically transparent insulation material. For example, the window WP may include glass or plastic. The front surface of the window WP may define the display surface FS of the display device DD. The display surface FS may include a transmission area TA and a bezel area BZA. The transmission area TA may be an optically transparent area. For example, the transmission area TA may have a visible light transmittance of about 90% or more.

The bezel area BZA may be an area having a relatively low light transmittance compared to the transmission area TA. The bezel area BZA may define a shape of the transmission area TA. The bezel area BZA may be adjacent to the transmission area TA and surround the transmission area TA. However, this is illustrated as an example, and the bezel area BZA of the window WP may be omitted. The window WP may include at least one functional layer among an anti-fingerprint layer, a hard coating layer, or an anti-reflection layer, and is not limited to any one embodiment.

The display module DM may be located below the window WP. The display module DM may be a component that substantially generates the image IM. The image IM generated by the display module DM is displayed on a display surface IS of the display module DM, and is externally visible to a user through the transmission area TA.

The display module DM may include a display area DA and a non-display area NDA. The display area DA may be an area that is activated in response to an electrical signal. The non-display area NDA may be adjacent to the display area DA. The non-display area NDA may surround the display area DA. The non-display area NDA may be an area covered by the bezel area BZA, and may not be visible from the outside.

The housing HAU may be coupled to the window WP. The housing HAU may be coupled to the window WP to provide an inner space (e.g., predetermined inner space). The display module DM may be accommodated in the inner space.

The housing HAU may include a material having relatively high rigidity. For example, the housing HAU may include a plurality of frames and/or plates, each of which includes glass, plastic, or metal, or is made of a combination thereof. The housing HAU may stably protect components of the display device DD accommodated in the inner space from external impact.

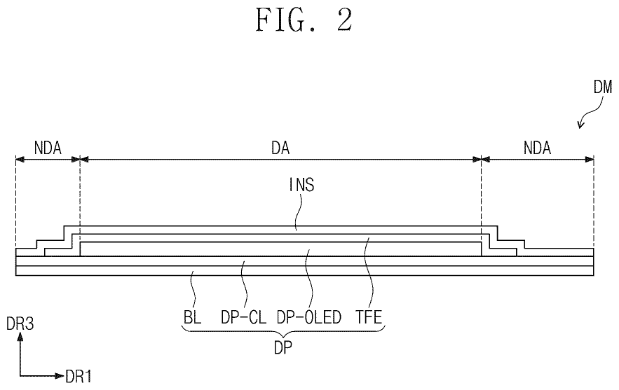

FIG. 2 is a cross-sectional view of a display module DM according to one or more embodiments of the present disclosure.

Referring to FIG. 2, the display module DM may include a display panel DP and an input sensor INS. In one or more embodiments, the display device DD (see FIG. 1A) according to one or more embodiments of the present disclosure may further include a protective member located on a bottom surface of the display panel DP, or an anti-reflection member and/or a window member that are located on a top surface of the input sensor INS.

The display panel DP may be a light-emitting display panel. However, this is an example, and the display panel DP is not particularly limited thereto. For example, the display panel DP may be an organic light-emitting display panel or an inorganic light-emitting display panel. A light-emitting layer in the organic light-emitting display panel may include an organic light-emitting material. A light-emitting layer in the inorganic light-emitting display panel may include a quantum dot, a quantum rod, or a micro LED. Hereinafter, the display panel DP is described as the organic light-emitting display panel.

The display panel DP may include a base layer BL, and a circuit element layer DP-CL, a display element layer DP-OLED, and a thin-film encapsulation layer TFE that are located on the base layer BL (as used herein, “located on” may mean “above”). The input sensor INS may be located directly on the thin-film encapsulation layer TFE. In the present disclosure, “a component A being located directly on a component B” means that an adhesive layer is not located between the component A and the component B.

The base layer BL may include at least one plastic film. The base layer BL may be a flexible substrate, and may include a plastic substrate, a glass substrate, a metal substrate, an organic/inorganic composite material substrate, or the like. The same/similar display area DA and non-display area NDA as/to those described with reference to FIG. 1B may be defined in the base layer BL.

The circuit element layer DP-CL may include at least one insulation layer and a circuit element. The insulation layer includes at least one inorganic layer and at least one organic layer. The circuit element includes signal lines, a driving circuit of a pixel, and the like.

The display element layer DP-OLED may include a partition wall and a light-emitting element. The light-emitting element may include an anode, an intermediate layer, and a cathode.

The thin-film encapsulation layer TFE may a plurality of thin films. Some of the thin films may improve optical efficiency, and some of the thin films may protect organic light-emitting diodes.

The input sensor INS obtains coordinate information of an external input. The input sensor INS may have a multilayer structure. The input sensor INS may include a conductive layer having a single-layer or multilayer structure. In addition, the input sensor INS may include an insulation layer having a single-layer or multilayer structure. The input sensor INS may detect an external input by using a capacitance method. However, this is an example, and one or more embodiments of the present disclosure is not limited thereto. For example, in one or more embodiments, the input sensor INS may detect an external input by using an electromagnetic induction method or a pressure detection method. In one or more other embodiments of the present disclosure, the input sensor INS may be omitted.

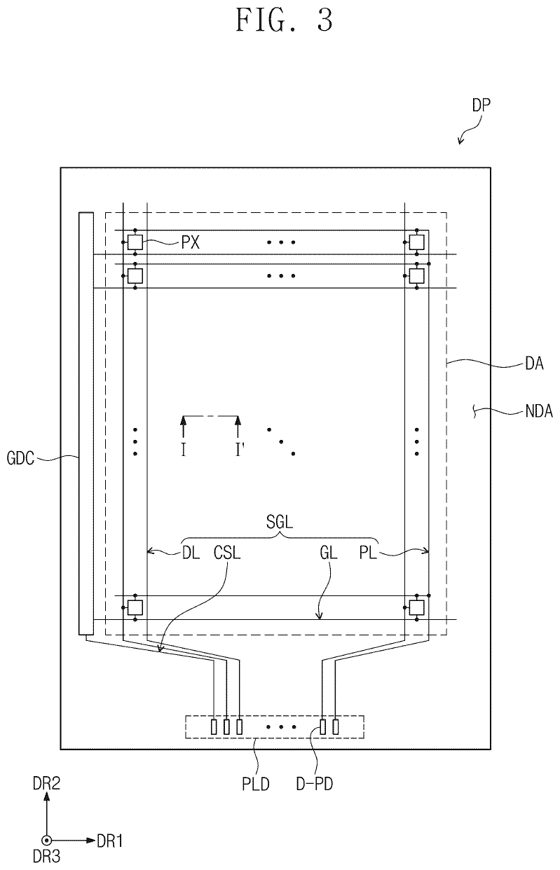

FIG. 3 is a plan view of a display panel according to one or more embodiments of the present disclosure.

Referring to FIG. 3, a display area DA, and a non-display area NDA around the display area DA may be defined in a display panel DP. The display panel DP may include pixels PX, and signal lines SGL electrically connected to the pixels PX. The display panel DP may include a driving circuit GDC and a pad part PLD. The display area DA and the non-display area NDA may be divided according to whether the pixels PX are located or are not located. The pixels PX may be located in the display area DA. The driving circuit GDC and the pad part PLD may be located in the non-display area NDA.

The pixels PX may be arranged in the first direction DR1 and the second direction DR2. The pixels PX may include a plurality of pixel rows, which extend in the first direction DR1 and are arranged in the second direction DR2, and a plurality of pixel columns which extend in the second direction DR2 and are arranged in the first direction DR1.

The signal lines SGL may include gate lines GL, data lines DL, a power line PL, and a control signal line CSL. Each of the gate lines GL may be connected to a corresponding pixel of the pixels PX, and each of the data lines DL may be connected to a corresponding pixel of the pixels PX. The power line PL may be electrically connected to the pixels PX. The control signal line CSL may be connected to the driving circuit GDC to provide the driving circuit GDC with control signals.

The driving circuit GDC may include a gate-driving circuit. The gate-driving circuit may generate gate signals, and may sequentially output the generated gate signals to the gate lines GL. The gate-driving circuit may further output another control signal to a pixel-driving circuit.

The pad part PLD may be a portion to which a flexible circuit board is connected. The pad part PLD may include pixel pads D-PD, and the pixel pads D-PD may be pads for connecting the flexible circuit board to the display panel DP. Each of the pixel pads D-PD may be connected to a corresponding signal line of the signal lines SGL. The pixel pads D-PD may be connected to corresponding pixels PX through the signal lines SGL, respectively. In addition, one pixel pad of the pixel pads D-PD may be connected to the driving circuit GDC.

In addition, the pad part PLD may further include input pads. The input pads may be pads for connecting the flexible circuit board to the input sensor INS (see FIG. 2). However, one or more embodiments of the present disclosure is not limited thereto, and the input pads may be located in the input sensor INS (see FIG. 2) to be connected to a separate circuit board from the pixel pads D-PD. Alternatively, the input sensor INS (see FIG. 2) may be omitted, and the pads PD may not further include input pads.

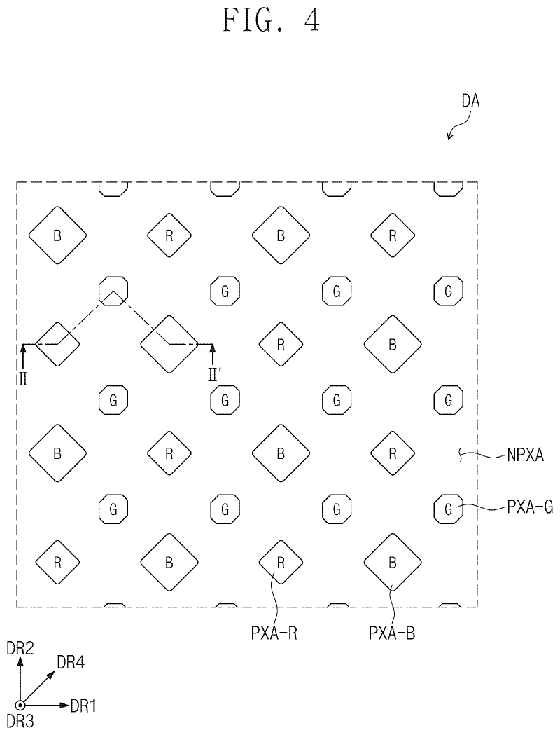

FIG. 4 is an enlarged plan view of a portion of the display area DA of the display panel DP (see FIG. 2) according to one or more embodiments of the present disclosure. FIG. 4 illustrates a plane of the display module DM (see FIG. 1B) when viewed on the display surface IS (see FIG. 1B) of the display module DM, and illustrates arrangement of light-emitting areas PXA-R, PXA-G, and PXA-B.

Referring to FIG. 4, the display area DA may include first to third light-emitting areas PXA-R, PXA-G, and PXA-B, and a peripheral area NPXA surrounding the first to third light-emitting areas PXA-R, PXA-G, and PXA-B. The first to third light-emitting areas PXA-R, PXA-G, and PXA-B may correspond respectively to areas from which light provided from light-emitting elements is emitted. The first to third light-emitting areas PXA-R, PXA-G, and PXA-B may be divided according to respective colors of light emitted toward the outside of the display module DM (see FIG. 2).

The first to third light-emitting areas PXA-R, PXA-G, and PXA-B may respectively provide light having first to third colors different from each other. For example, the light having the first color may be red light, the light having the second color may be green light, and the light having the third color may be blue light. However, examples of the light having the first to third colors are not necessarily limited to the foregoing examples.

Each of the first to third light-emitting areas PXA-R, PXA-G, and PXA-B may be defined as an area in which a top surface of an anode is exposed by a light-emitting opening to be described later. The peripheral area NPXA may set a boundary of each of the first to third light-emitting areas PXA-R, PXA-G, and PXA-B, and may reduce or prevent mixture of colors between the first to third light-emitting areas PXA-R, PXA-G, and PXA-B.

Each of the first to third light-emitting areas PXA-R, PXA-G, and PXA-B may be provided in plurality to have an arrangement shape (e.g., predetermined arrangement shape), and may be repeatedly located in the display area DA. For example, the first and third light-emitting areas PXA-R and PXA-B may be alternately arranged in the first direction DR1 to constitute a “first group.” The second light-emitting areas PXA-G may be arranged in the first direction DR1 to constitute a “second group.” Each of the “first group” and the “second group” may be provided in plurality, and the “first groups” and the “second groups” may be alternately arranged in the second direction DR2.

One second light-emitting area PXA-G may be spaced apart from one first light-emitting area PXA-R or one third light-emitting area PXA-B in a fourth direction DR4. The fourth direction DR4 may be defined as a direction between the first and second directions DR1 and DR2.

FIG. 4 illustrates an example of the arrangement shape or patten of the first to third light-emitting areas PXA-R, PXA-G, and PXA-B. However, one or more embodiments of the present disclosure is not limited thereto, and the first to third light-emitting areas PXA-R, PXA-G, and PXA-B may be arranged in various shapes. In one or more embodiments, the first to third light-emitting areas PXA-R, PXA-G, and PXA-B may have a PENTILE™ arrangement shape as illustrated in FIG. 4 (PENTILE™ being a registered trademark of Samsung Display Co., Ltd., Republic of Korea). Alternatively, the first to third light-emitting areas PXA-R, PXA-G, and PXA-B may have a stripe arrangement shape or a diamond (e.g., Diamond Pixel™) arrangement shape (Diamond Pixel™ being a registered trademark of Samsung Display Co., Ltd., Republic of Korea).

Each of the first to third light-emitting areas PXA-R, PXA-G, and PXA-B may have various shapes on a plane. For example, each of the first to third light-emitting areas PXA-R, PXA-G, and PXA-B may have a shape, such as a polygonal, circular, or oval shape. As an example, FIG. 4 illustrates the first and third light-emitting areas PXA-R and PXA-B each having a square (or rhombus) shape and the second light-emitting area PXA-G having an octagonal shape on a plane.

The first to third light-emitting areas PXA-R, PXA-G, and PXA-B may have the same shape, or at least some thereof may have different shapes from each other on a plane. As an example, FIG. 4 illustrates the first and third light-emitting areas PXA-R and PXA-B having the same shape, and the second light-emitting area PXA-G having a different shape from the first and third light-emitting areas PXA-R and PXA-B on a plane.

At least some of the first to third light-emitting areas PXA-R, PXA-G, and PXA-B may have different surface areas on a plane. In one or more embodiments, a surface area of the first light-emitting area PXA-R that emits the red light may be greater than a surface area of the second light-emitting area PXA-G that emits the green light, and may be less than a surface area of the third light-emitting area PXA-B that emits the blue light. However, a large-to-small relationship between the surface areas of the first to third light-emitting areas PXA-R, PXA-G, and PXA-B according to the colors of the emitted light is not limited thereto, and may be varied according to design of the display module DM (see FIG. 2). However, one or more embodiments of the present disclosure is not limited thereto, and the first to third light-emitting areas PXA-R, PXA-G, and PXA-B may have the same surface area on a plane.

The shape, surface area, arrangement, and the like of the first to third light-emitting areas PXA-R, PXA-G, and PXA-B of the display module DM (see FIG. 2) according to one or more embodiments of the present disclosure may be variously designed according to the color of the emitted light or the size or configuration of the display module DM (see FIG. 2), and are not limited to the one or more embodiments corresponding to FIG. 4.

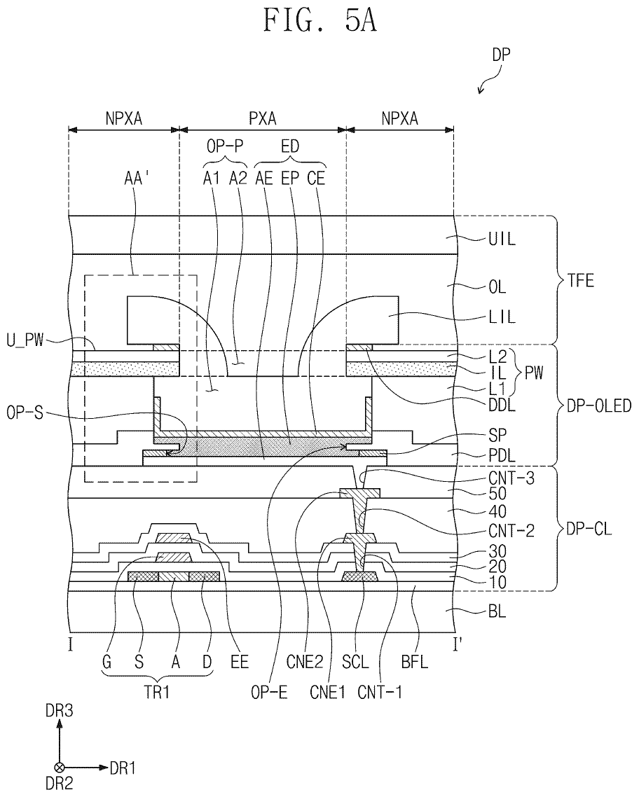

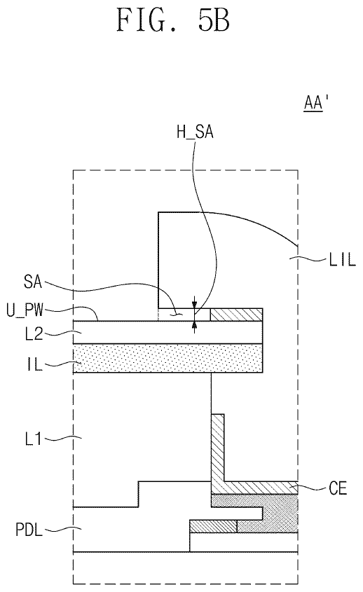

FIG. 5A is a cross-sectional view of the display panel taken along the line I-I′ in FIG. 3. FIG. 5B is an enlarged view of area AA′ in FIG. 5A. In one or more embodiments to be described with reference to FIGS. 5A and 5B, FIG. 2 is referred to, and components designated by like reference numbers or symbols are not described. FIG. 5A illustrates an enlarged view of one light-emitting area PXA in the display area DA (see FIG. 4), and the light-emitting area PXA in FIG. 5 may correspond to any one of the first to third light-emitting areas PXA-R, PXA-G, and PXA-B in FIG. 4.

Referring to FIGS. 5A and 5B, a display panel DP may include a base layer BL, a circuit element layer DP-CL, a display element layer DP-OLED, and a thin-film encapsulation layer TFE.

The display panel DP may include a plurality of insulation layers, a semiconductor pattern, a conductive pattern, a signal line, and the like. The insulation layers, a semiconductor layer, and a conductive layer are formed through coating, deposition, or the like. Thereafter, the insulation layers, the semiconductor layer, and the conductive layer may be selectively patterned through a photolithography process and an etching process. The semiconductor pattern, the conductive pattern, the signal line, and the like, which are included in the circuit element layer DP-CL and the display element layer DP-OLED, may be formed through those processes.

The circuit element layer DP-CL may be located on the base layer BL. The circuit element layer DP-CL may include a buffer layer BFL, a transistor TR1, a signal transmission area SCL, first to fifth insulation layers 10, 20, 30, 40 and 50, an electrode EE, and a plurality of connection electrodes CNE1 and CNE2.

The buffer layer BFL may be located on the base layer BL. The buffer layer BFL may improve bonding force between the base layer BL and the semiconductor pattern. The buffer layer BFL may include a silicon oxide layer and a silicon nitride layer. The silicon oxide layer and the silicon nitride layer may be alternately stacked.

The semiconductor pattern may be located on the buffer layer BFL. The semiconductor pattern may include polysilicon. However, one or more embodiments of the present disclosure is not limited thereto, and the semiconductor pattern may also include amorphous silicon or a metal oxide. FIG. 5A just illustrates a portion of the semiconductor pattern as an example, and the semiconductor pattern may be further located in the plurality of light-emitting areas PXA-R, PXA-G, and PXA-B (see FIG. 4). The semiconductor pattern may be arranged over the plurality of light-emitting areas PXA-R, PXA-G, and PXA-B according to a corresponding rule. The semiconductor pattern may have different electrical properties according to whether or not the semiconductor pattern is doped. The semiconductor pattern may include a first region having a high doping concentration, and a second region having a low doping concentration. The first region may be doped with an n-type dopant or a p-type dopant. A p-type transistor may include the first region doped with the p-type dopant.

The first region has higher conductivity than the second region, and substantially serves as an electrode or a signal line. The second region may substantially correspond to an active (or channel) of a transistor. In other words, one portion of the semiconductor pattern may be an active of the transistor, another portion thereof may be a source or a drain of the transistor, and still another portion thereof may be a conductive region.

A source S, an active A, and a drain D of the transistor TR1 may be provided from the semiconductor pattern. FIG. 5A illustrates a portion of the signal transmission area SCL provided from the semiconductor pattern. In one or more embodiments, the signal transmission area SCL may be connected to the drain D of the transistor TR1 on a plane.

The first to fifth insulation layers 10, 20, 30, 40 and 50 may be located on the buffer layer BFL. Each of the first to fifth insulation layers 10, 20, 30, 40 and 50 may be an inorganic layer or an organic layer.

The first insulation layer 10 may be located on the buffer layer BFL. The first insulation layer 10 may cover the source S, the active A, and the drain D of the transistor TR1, and the signal transmission area SCL, which are located on the buffer layer BFL. A gate G of the transistor TR1 may be located on the first insulation layer 10. The second insulation layer 20 may be located on the first insulation layer 10 to cover the gate G. The electrode EE may be located on the second insulation layer 20. The third insulation layer 30 may be located on the second insulation layer 20 to cover the electrode EE.

A first connection electrode CNE1 may be located on the third insulation layer 30. The first connection electrode CNE1 may be connected to the signal transmission area SCL through a contact hole CNT-1 passing through the first to third insulation layers 10, 20 and 30. The fourth insulation layer 40 may be located on the third insulation layer 30 to cover the first connection electrode CNE1. The fourth insulation layer 40 may be an organic layer.

A second connection electrode CNE2 may be located on the fourth insulation layer 40. The second connection electrode CNE2 may be connected to the first connection electrode CNE1 through a contact hole CNT-2 passing through the fourth insulation layer 40. The fifth insulation layer 50 may be located on the fourth insulation layer 40 to cover the second connection electrode CNE2. The fifth insulation layer 50 may be an organic layer.

The display element layer DP-OLED may be located on the circuit element layer DP-CL. The display element layer DP-OLED may include a light-emitting element ED, a sacrificial pattern SP, a pixel-defining film PDL, a partition wall PW, and a dummy layer DDL.

The light-emitting element ED may include an anode AE (or first electrode), a light-emitting pattern EP, and a cathode CE (or second electrode). The light-emitting element ED may be located in a light-emitting opening OP-E and a partition wall opening OP-P that will be described later.

The anode AE may be located on the fifth insulation layer 50 of the circuit element layer DP-CL. The anode AE may be a transmissive electrode, a semi-transmissive electrode, or a reflective electrode. The anode AE may be connected to the second connection electrode CNE2 through a connection contact hole CNT-3 passing through, and defined in, the fifth insulation layer 50. Thus, the anode AE may be electrically connected to the signal transmission area SCL through the first and second connection electrodes CNE1 and CNE2, and may be electrically connected to a corresponding circuit element. The anode AE may have a single-layer structure or a multilayer structure. The anode AE may include a plurality of layers including ITO or Ag. For example, the anode AE may include a layer including ITO (hereinafter referred to as a lower ITO layer), a layer located on the lower ITO layer and including Ag (hereinafter referred to as an Ag layer), and a layer located on the Ag layer and including ITO (hereinafter referred to as an upper ITO layer).

The sacrificial pattern SP may be located between the anode AE and the pixel-defining film PDL. A sacrificial opening OP-S that exposes a portion of a top surface of the anode AE may be defined (or had) in the sacrificial pattern SP. The sacrificial opening OP-S may overlap the light-emitting opening OP-E to be described later.

The pixel-defining film PDL may be located on the fifth insulation layer 50 of the circuit element layer DP-CL. The light-emitting opening OP-E may be defined (or had) in the pixel-defining film PDL. The light-emitting opening OP-E may correspond to the anode AE, and the pixel-defining film PDL may expose at least a portion of the anode AE through the light-emitting opening OP-E.

In addition, the light-emitting opening OP-E may correspond to the sacrificial opening OP-S of the sacrificial pattern SP. The top surface of the anode AE may be spaced apart from the pixel-defining film PDL with the sacrificial pattern SP therebetween on a cross-section, and accordingly, the anode AE may be protected against damage in a process of forming the light-emitting opening OP-E.

A surface area of the light-emitting opening OP-E may be less than a surface area of the sacrificial opening OP-S on a plane. That is, an inner side surface of the pixel-defining film PDL, which defines the light-emitting opening OP-E, may be more adjacent to a center of the anode AE (e.g., in plan view) than an inner side surface of the sacrificial pattern SP, which defines the sacrificial opening OP-S. However, one or more embodiments of the present disclosure is not limited thereto, and the inner side surface of the sacrificial pattern SP, which defines the sacrificial opening OP-S, may be substantially aligned with the inner side surface of the pixel-defining film PDL, which defines the light-emitting opening OP-E. Here, the light-emitting area PXA may be considered to be an area of the anode AE that is exposed from a corresponding sacrificial opening OP-S.

The pixel-defining film PDL may include an inorganic insulation material. For example, the pixel-defining film PDL may include a silicon nitride (SiNₓ). The pixel-defining film PDL may be located between the anode AE and the partition wall PW to block an electrical connection between the anode AE and the partition wall PW.

The light-emitting pattern EP may be located on the anode AE. The light-emitting pattern EP may include a light-emitting layer including a light-emitting material. The light-emitting pattern EP may further include a hole injection layer HIL and a hole transport layer HTL, which are located between the anode AE and the light-emitting layer, and may further include an electron transport layer ETL and an electron injection layer EIL, which are located on the light-emitting layer. The light-emitting pattern EP may be referred to as an “organic layer” or an “intermediate layer.”

The light-emitting pattern EP may be patterned by a tip part defined in the partition wall PW. Details will be described later when a method for manufacturing a display panel is described. The light-emitting pattern EP may be located inside the sacrificial opening OP-S and the light-emitting opening OP-E. However, this is illustrated as an example, and the light-emitting pattern EP may be located inside at least one of the sacrificial opening OP-S, the light-emitting opening OP-E, or the partition wall opening OP-P. The light-emitting pattern EP may cover a top surface of a portion of the pixel-defining film PDL.

The cathode CE may be located on the light-emitting pattern EP. The cathode CE may be patterned by the tip part defined in the partition wall PW. At least a portion of the cathode CE may be located in the partition wall opening OP-P, and a portion of a cathode layer patterned by the tip part may provide the dummy layer DDL. The dummy layer DDL may include the same material as the cathode CE, and may be located in a portion of a separation area SA to be described later with respect to FIG. 5B. In this case, the dummy layer DDL may be referred to as a cathode dummy layer DDL. FIG. 5A illustrates an example in which the cathode CE is located in the light-emitting opening OP-E and the partition wall opening OP-P. However, one or more embodiments of the present disclosure is not limited thereto. For example, the cathode CE may be located only in the partition wall opening OP-P.

The cathode CE may extend along an inner side surface of a first partition wall layer L1, and an end of the cathode CE may contact the first partition wall layer L1. FIG. 5A illustrates an example in which the cathode CE contacts the inner side surface of the first partition wall layer L1 and an inner side surface of the pixel-defining film PDL. However, one or more embodiments of the present disclosure is not limited thereto. For example, the cathode CE may contact only the inner side surface of the first partition wall layer L1.

The cathode CE may have conductivity. The cathode CE may be made of various materials, such as a metal, a transparent conductive oxide (TCO), or a conductive polymeric material, as long as the cathode CE is capable of having conductivity. For example, the cathode CE may include silver (Ag), magnesium (Mg), lead (Pb), copper (Cu), or a compound thereof.

The partition wall PW may be located on the pixel-defining film PDL. The partition wall opening OP-P may be defined in the partition wall PW. The partition wall opening OP-P may overlap the light-emitting opening OP-E, and may expose at least a portion of the anode AE.

The partition wall PW may include a plurality of layers stacked in sequence. For example, the partition wall PW may include the first partition wall layer L1, a partition wall insulation layer IL, and a second partition wall layer L2. The first partition wall layer L1 may be located on the pixel-defining film PDL, the partition wall insulation layer IL may be located on the first partition wall layer L1, and the second partition wall layer L2 may be located on the partition wall insulation layer IL. As illustrated in FIG. 5A, the first partition wall layer L1 may have a thickness that is greater than a thickness of each of the partition wall insulation layer IL and the second partition wall layer L2. However, one or more embodiments of the present disclosure is not limited thereto.

Each of the first partition wall layer L1 and the second partition wall layer L2 may include a conductive material. For example, the conductive material may include a metal, a transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), tungsten (W), or an alloy. The transparent conductive oxide may include an indium tin oxide (ITO), an indium zinc oxide (IZO), a zinc oxide, an indium oxide, an indium gallium oxide, an indium gallium zinc oxide (IGZO), or an aluminum zinc oxide. The materials of the first and second partition wall layers L1 and L2 are examples, and are not limited to the foregoing examples.

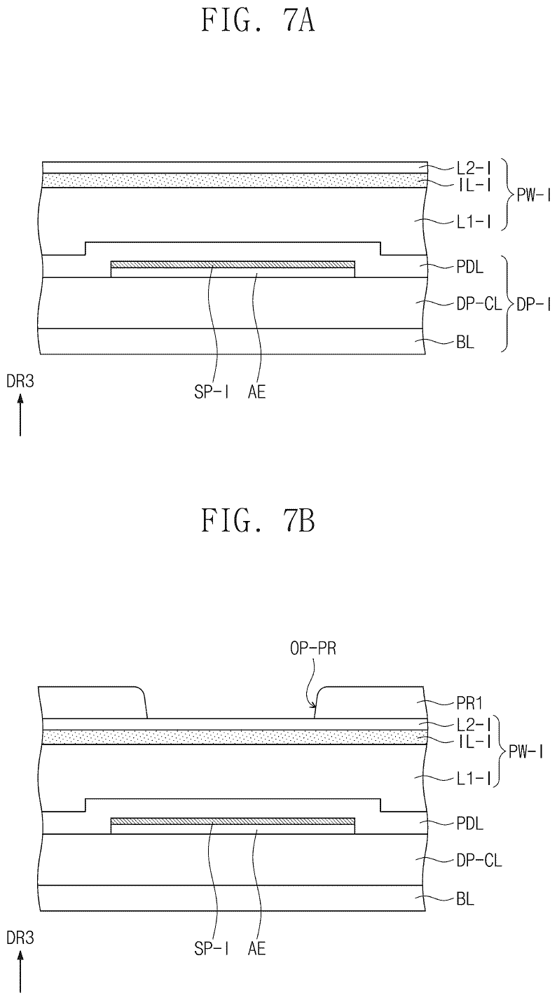

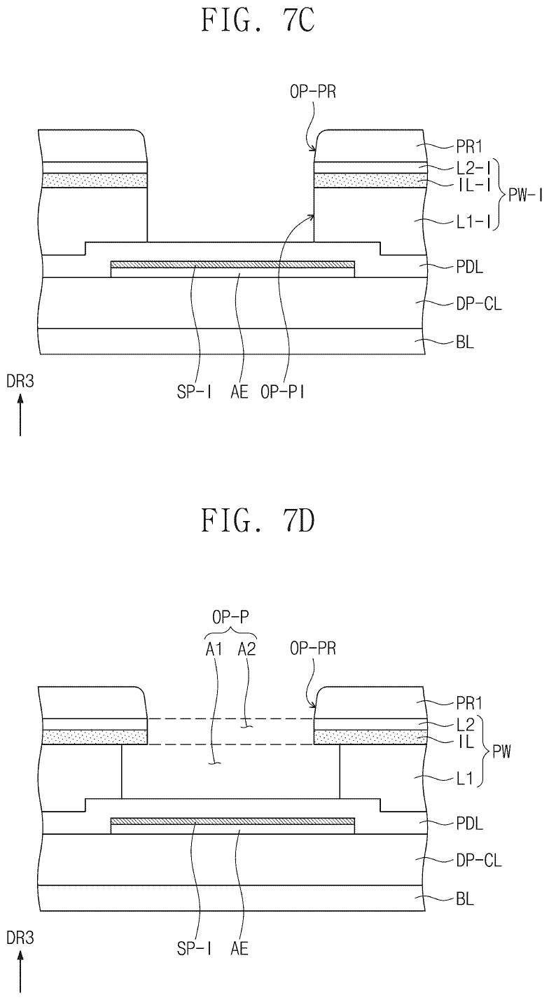

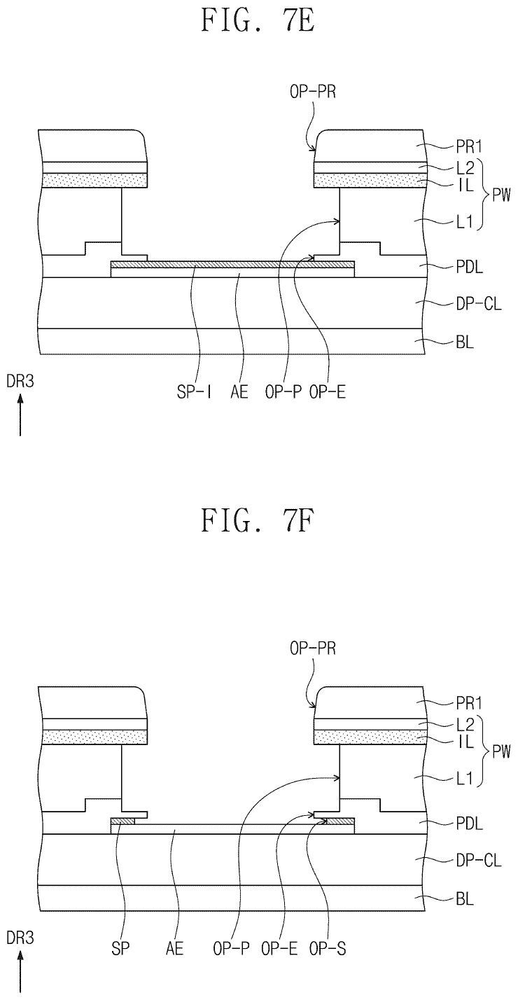

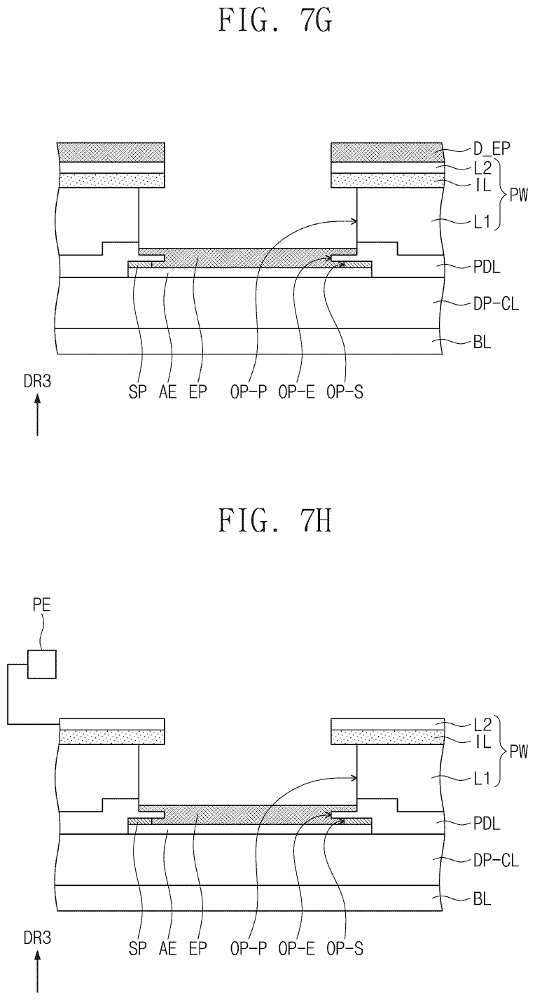

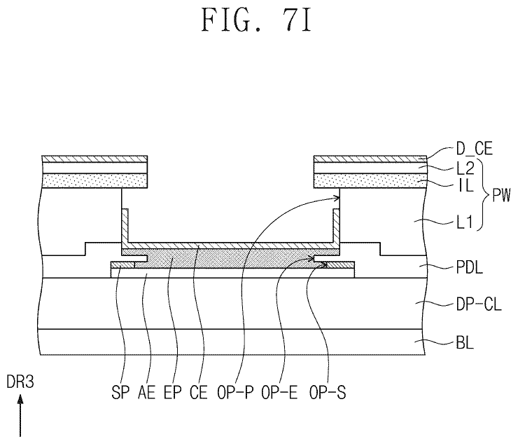

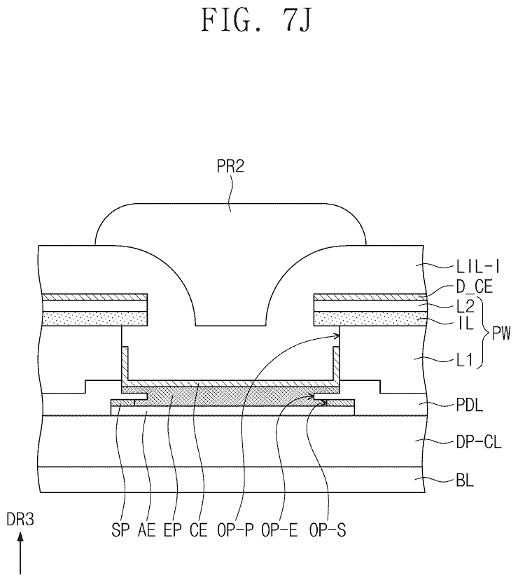

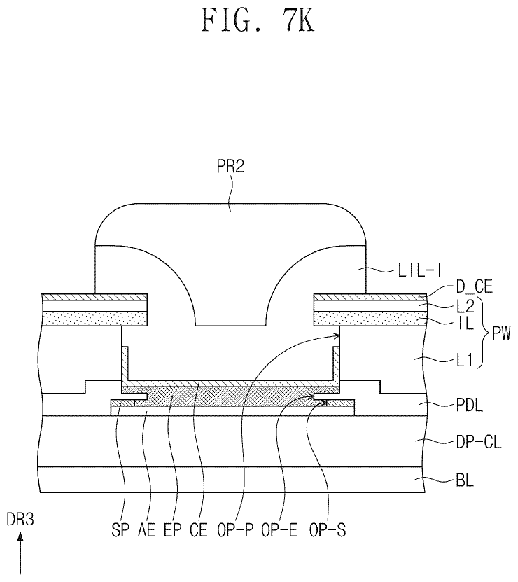

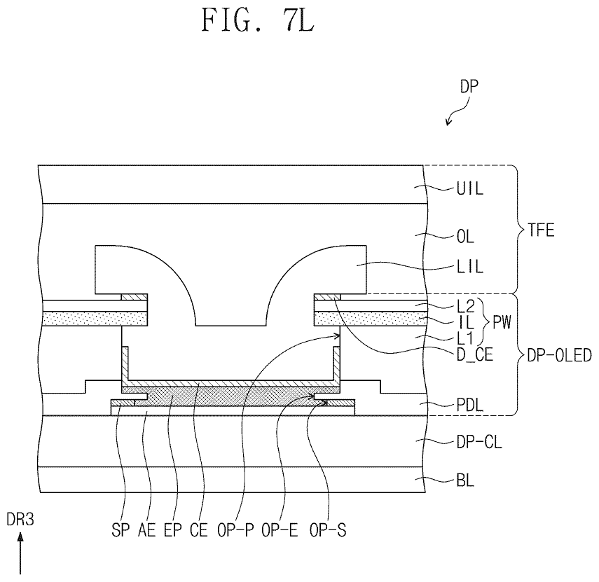

For example, the second partition wall layer L2 may include a material having a characteristic of a melting point of about 970 degrees or more. In one or more embodiments, the second partition wall layer L2 may include at least one of titanium (Ti), molybdenum (Mo), or tungsten (W). In the manufacture of the display panel, a voltage may be applied to the second partition wall layer L2 to remove the dummy layer DDL formed concurrently or substantially simultaneously with deposition of the light-emitting pattern EP. For example, a voltage may be applied to the second partition wall layer L2 to cause Joule heating. Details will be described with reference to FIGS. 7A to 7L.

The partition wall insulation layer IL may include an insulation material. The partition wall insulation layer IL may be located between the first partition wall layer L1 and the second partition wall layer L2 to block an electrical connection between the first partition wall layer L1 and the second partition wall layer L2. For example, as the partition wall insulation layer IL including an insulation material is included, when a voltage is applied to the second partition wall layer L2, and thus current flows through the second partition wall layer L2, the current flowing to the first partition wall layer L1 may be reduced or prevented.

The partition wall PW may have an undercut shape on a cross-section. At least one of the plurality of layers of the partition wall PW may be recessed from the other layers, and accordingly, the partition wall PW may include the tip part. For example, the first partition wall layer L1 may have an undercut shape with respect to each of the partition wall insulation layer IL and the second partition wall layer L2. The partition wall insulation layer IL and the second partition wall layer L2 may protrude from the first partition wall layer L1 toward the light-emitting opening OP-E to provide the tip part. A portion of each of the partition wall insulation layer IL and the second partition wall layer L2, which protrudes from the first partition wall layer L1 toward the light-emitting area PXA, may be defined as the tip part in the partition wall PW. That is, each of an inner side surface of the partition wall insulation layer IL and an inner side surface of the second partition wall layer L2 may be closer to the center of the anode AE (e.g., in plan view) than the inner side surface of the first partition wall layer L1.

The partition wall opening OP-P of the partition wall PW may include a first area A1 and a second area A2. The first area A1 may be defined by the inner side surface of the first partition wall layer L1, and the second area A2 may be defined by the inner side surface of the partition wall insulation layer IL and the inner side surface of the second partition wall layer L2. A width of the first area A1 in one direction (e.g., first direction DR1 or second direction DR2, or in plan view) may be greater than a width of the second area A2 in the one direction (e.g., first direction DR1 or second direction DR2).

FIG. 5A illustrates an example in which each of the inner side surface of the first partition wall layer L1, the inner side surface of the partition wall insulation layer IL, and the inner side surface of the second partition wall layer L2 is perpendicular to the top surface of the pixel-defining film PDL. However, one or more embodiments of the present disclosure is not limited thereto. For example, the partition wall PW may have a tapered shape, or may have a reverse tapered shape.

The partition wall PW may receive a driving voltage, and accordingly, the cathode CE may be electrically connected to the partition wall PW to receive the driving voltage.

The thin-film encapsulation layer TFE may be located on the display element layer DP-OLED. The thin-film encapsulation layer TFE may include a lower inorganic encapsulation pattern LIL, an organic encapsulation film OL, and an upper inorganic encapsulation film UIL.

The lower inorganic encapsulation pattern LIL may correspond to (overlap) the light-emitting opening OP-E. The lower inorganic encapsulation pattern LIL may cover the light-emitting element ED. A portion of the lower inorganic encapsulation pattern LIL may be provided in the partition wall opening OP-P, and another portion of the lower inorganic encapsulation pattern LIL may be provided on the partition wall PW. The other portion of the lower inorganic encapsulation pattern LIL may be spaced apart from a top surface U_PW of the partition wall PW on a cross-section.

As shown in FIG. 5B, the separation area SA may be defined between the lower inorganic encapsulation pattern LIL and the partition wall PW. The separation area SA may have a height (e.g., thickness) H_SA that corresponds to a height (e.g., thickness) of the cathode CE. That is, the height H_SA of the separation area SA may be substantially the same as a thickness of the cathode CE located in the partition wall opening OP-P, or a thickness of the dummy layer DDL provided inside the separation area SA. In one or more embodiments, the height H_SA of the separation area SA may be about 200 angstrom (Å) or less.

FIG. 5A illustrates an example in which the cathode dummy layer DDL is located in the separation area SA. However, the separation area SA may be empty in one or more other embodiments. That is, the cathode dummy layer DDL may be omitted from the separation area SA. In this case, the entirety of the cathode dummy layer DDL may be removed by wet etching.

The organic encapsulation film OL may be located on the lower inorganic encapsulation pattern LIL. The organic encapsulation film OL may cover the lower inorganic encapsulation pattern LIL, and may provide a flat top surface. The upper inorganic encapsulation film UIL may be located on the organic encapsulation film OL. The lower inorganic encapsulation pattern LIL, a common inorganic film, and the upper inorganic encapsulation film UIL may protect the display element layer DP-OLED from moisture/oxygen, and the organic encapsulation film OL may protect the display element layer DP-OLED from foreign matters, such as dust particles.

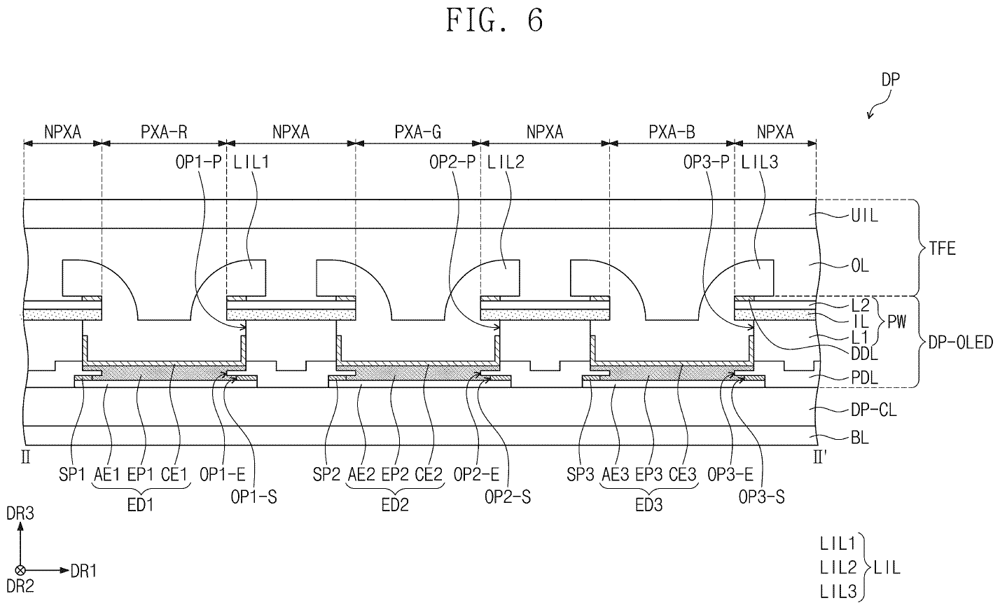

FIG. 6 is a cross-sectional view taken along the line II-II′ in FIG. 4. FIG. 6 illustrates an enlarged view of one first light-emitting area PXA-R, one second light-emitting area PXA-G, and one third light-emitting area PXA-B, and the same/similar description of the one light-emitting area PXA in FIG. 5A may apply to each of the first to third light-emitting areas PXA-R, PXA-G, and PXA-B in FIG. 6. FIG. 6 will be described by denoting the same/similar components as/to those described with reference to FIG. 5A as the same/similar reference numbers or symbols, and omitting redundant description.

Referring to FIG. 6, a display panel DP may include a base layer BL, a circuit element layer DP-CL, a display element layer DP-OLED, and a thin-film encapsulation layer TFE. The display element layer DP-OLED may include light-emitting elements ED1, ED2 and ED3, sacrificial patterns SP1, SP2 and SP3, a pixel-defining film PDL, a partition wall PW, and a dummy layer DDL.

The light-emitting elements ED1, ED2 and ED3 may include a first light-emitting element ED1, a second light-emitting element ED2, and a third light-emitting element ED3 that emit light respectively having different colors from each other. Each of the first light-emitting element ED1, the second light-emitting element ED2, and the third light-emitting element ED3 may be provided in plurality, but hereinafter is referred to in a singular form for convenience of explanation.

The first light-emitting element ED1 may include a first anode AE1, a first light-emitting pattern EP1, and a first cathode CE1. The second light-emitting element ED2 may include a second anode AE2, a second light-emitting pattern EP2, and a second cathode CE2. The third light-emitting element ED3 may include a third anode AE3, a third light-emitting pattern EP3, and a third cathode CE3. The first to third anodes AE1, AE2 and AE3 may be provided as a plurality of patterns. In one or more embodiments, the first light-emitting pattern EP1 may provide light having a red color, the second light-emitting pattern EP2 may provide light having a green color, and the third light-emitting pattern EP3 may provide light having a blue color.

First to third light-emitting openings OP1-E, OP2-E and OP3-E may be defined in the pixel-defining film PDL. The first light-emitting opening OP1-E may expose at least a portion of the first anode AE1. The second light-emitting opening OP2-E may expose at least a portion of the second anode AE2. The third light-emitting opening OP3-E may expose at least a portion of the third anode AE3.

The first light-emitting area PXA-R may be defined as an area, which is exposed by the first light-emitting opening OP1-E, of a top surface of the first anode AE1. The second light-emitting area PXA-G may be defined as an area, which is exposed by the second light-emitting opening OP2-E, of a top surface of the second anode AE2. The third light-emitting area PXA-B may be defined as an area, which is exposed by the third light-emitting opening OP3-E, of a top surface of the third anode AE3.

The sacrificial patterns SP1, SP2 and SP3 may include a first sacrificial pattern SP1, a second sacrificial pattern SP2, and a third sacrificial pattern SP3. The first to third sacrificial patterns SP1, SP2 and SP3 may be located on the top surfaces on the first to third anodes AE1, AE2 and AE3, respectively. First to third sacrificial openings OP1-S, OP2-S and OP3-S overlapping the first to third light-emitting openings OP1-E, OP2-E and OP3-E may be defined in the first to third sacrificial patterns SP1, SP2 and SP3, respectively.

First to third partition wall openings OP1-P, OP2-P and OP3-P overlapping the first to third light-emitting openings OP1-E, OP2-E and OP3-E, respectively, may be defined in the partition wall PW.

The first to third light-emitting patterns EP1, EP2 and EP3 and the first to third cathodes CE1, CE2 and CE3 may be separated from each other physically by a partition wall insulation layer IL and a second partition wall layer L2, which provide a tip part, and may be provided in the light-emitting openings OP1-E, OP2-E and OP3-E and the partition wall openings OP1-P, OP2-P and OP3-P. That is, the light-emitting elements ED1, ED2 and ED3 may be located in the partition wall openings OP1-P, OP2-P and OP3-P and the light-emitting openings OP1-E, OP2-E and OP3-E. For example, the first light-emitting element ED1 may be located in the first partition wall opening OP1-P and the first light-emitting opening OP1-E, the second light-emitting element ED2 may be located in the second partition wall opening OP2-P and the second light-emitting opening OP2-E, and the third light-emitting element ED3 may be located in the third partition wall opening OP3-P and the third light-emitting opening OP3-E.

According to one or more embodiments of the present disclosure, the plurality of first light-emitting patterns EP1 may be deposited by being patterned into pixel units by the tip part defined in the partition wall PW. That is, the first light-emitting patterns EP1 may be formed in common using an open mask, but may be suitably separated into the pixel units by the partition wall PW.

On the other hand, when a fine metal mask (FMM) is used to pattern the first light-emitting patterns EP1, a support spacer protruding from a conductive partition wall may be typically provided to support the fine metal mask. In addition, as the fine metal mask is spaced from a height of the partition wall and the spacer from a base surface that is subjected to patterning, achievement of high resolution may be restricted. Moreover, as the fine metal mask contacts the spacer, a foreign matter may remain on the spacer, or the spacer may be damaged due to stabbing of the fine metal mask after a process of patterning the first light-emitting patterns EP1. Accordingly, a defective display panel may thereby result.

As the partition wall PW is included, physical separation between the light-emitting elements ED1, ED2 and ED3 may be suitably achieved. Accordingly, drive errors or current leakage between adjacent light-emitting areas PXA-R, PXA-G, and PXA-B may be reduced or prevented, and the light-emitting elements ED1, ED2 and ED3 may be capable of being driven independently of each other.

For example, as the plurality of first light-emitting patterns EP1 are patterned without a mask contacting inner components in the display area DA (see FIG. 1B), a defect rate may be reduced to provide the display panel DP with improved process reliability. As the patterning is enabled even when a separate support spacer protruding from the partition wall PW is not provided, the respective surface areas of the light-emitting areas PXA-R, PXA-G, and PXA-B may be miniaturized to provide the display panel DP suitably implemented at high resolution.

In addition, as manufacture of a mask having a large surface area is omitted from the manufacture of the display panel DP having a large surface area, process costs may be reduced, and the display panel DP may not be affected by a defect likely to occur in the mask having a large surface area. Accordingly, the display panel DP with improved process reliability may be provided. The same/similar description of the plurality of the first light-emitting patterns EP1 may apply to the plurality of the second and third light-emitting patterns EP2 and EP3.

The thin-film encapsulation layer TFE may include lower inorganic encapsulation patterns LIL, an organic encapsulation film OL, and an upper inorganic encapsulation film UIL.

The lower inorganic encapsulation patterns LIL may include a first lower inorganic encapsulation pattern LIL1 that covers the first light-emitting element ED1, a second lower inorganic encapsulation pattern LIL2 that covers the second light-emitting element ED2, and a third lower inorganic encapsulation pattern LIL3 that covers the third light-emitting element ED3. The first to third lower inorganic encapsulation patterns LIL1, LIL2 and LIL3 may overlap the first to third light-emitting openings OP1-E, OP2-E and OP3-E, respectively. The first to third lower inorganic encapsulation patterns LIL1, LIL2 and LIL3 may be provided in the form of patterns spaced apart from each other.

A portion of the first lower inorganic encapsulation pattern LIL1 may be defined in the partition wall opening OP-P, and another portion of the first lower inorganic encapsulation pattern LIL1 may be defined on the partition wall PW. The other portion of the first lower inorganic encapsulation pattern LIL1 defined on the partition wall PW may be spaced apart from a top surface of the partition wall PW on a cross-section.

A portion of the second lower inorganic encapsulation pattern LIL2 may be defined in the partition wall opening OP-P, and another portion of the second lower inorganic encapsulation pattern LIL2 may be defined on the partition wall PW. The other portion of the second lower inorganic encapsulation pattern LIL2 defined on the partition wall PW may be spaced apart from the top surface of the partition wall PW on a cross-section.

A portion of the third lower inorganic encapsulation pattern LIL3 may be defined in the partition wall opening OP-P, and another portion of the third lower inorganic encapsulation pattern LIL3 may be defined on the partition wall PW. The other portion of the third lower inorganic encapsulation pattern LIL3 defined on the partition wall PW may be spaced apart from the top surface of the partition wall PW on a cross-section.

A separation area SA may be defined between each of the first to third lower inorganic encapsulation patterns LIL1, LIL2 and LIL3 and the partition wall PW. A height (e.g., thickness) of the separation area SA may correspond to (e.g., may be substantially equal to) a height (e.g., thickness) of the cathode CE.

Typically, a height of a separation area corresponds to the sum of a thickness of a cathode and a thickness of a light-emitting pattern, and as the height of the separation area is great, over-etching (e.g., loss of a side surface part) of a lower inorganic encapsulation pattern may occur in the manufacture of the display panel.

Referring to FIGS. 5A to 6, the height H_SA of the separation area SA may correspond to the height of the cathode CE, and the height H_SA of the separation area SA may be relatively small. As the height H_SA of the separation area SA is remarkably less than a deposition thickness (e.g., about 2000 angstrom to about 3000 angstrom) of the light-emitting pattern EP, a subsequent light-emitting pattern may not be located in the separation area SA. For example, with respect to the separation area SA corresponding to the first light-emitting pattern EP1, the second and third light-emitting patterns EP2 and EP3 may not be located in the separation area corresponding to the first light-emitting pattern EP1 during the deposition of the second and third light-emitting patterns EP2 and EP3. Thus, in the manufacture of the display panel, over-etching of the lower inorganic encapsulation pattern may be reduced or removed, and a display panel defect due to water vapor transmission may be improved.

FIGS. 7A to 7L are cross-sectional views illustrating some of operations of a method for manufacturing a display panel according to one or more embodiments of the present disclosure. FIGS. 7A to 7L will be described by denoting the same/similar components as/to those described with reference to FIGS. 1 to 6 with the same/similar reference numbers or symbols, and by omitting redundant description.

The method for manufacturing the display panel according to one or more embodiments of the present disclosure may include providing a preliminary display panel including a base layer, and a pixel-defining film located on the base layer, may include forming, on the pixel-defining film, a preliminary partition wall including a first preliminary partition wall layer including a conductive material, a preliminary partition wall insulation layer including an insulation material, and a second preliminary partition wall layer including a conductive material, may include forming a partition wall having a partition wall opening from the preliminary partition wall, may include etching the pixel-defining film to form a light-emitting opening overlapping the partition wall opening, may include forming a light-emitting pattern in the light-emitting opening, and a light-emitting pattern dummy layer, which includes the same material as the light-emitting pattern, on the partition wall, and may include applying heat to the partition wall to remove the light-emitting pattern dummy layer.

Hereinafter, a method for forming one light-emitting element ED, and for forming a lower inorganic encapsulation pattern LIL that covers the light-emitting element ED, an organic encapsulation film OL, and an upper inorganic encapsulation film UIL, will be described with reference to FIGS. 7A to 7L. A display panel DP formed through the method described with reference to FIGS. 7A to 7L may correspond to the display panel DP in FIG. 5A.

Referring to FIG. 7A, the method for manufacturing the display panel according to one or more embodiments of the present disclosure may include providing a preliminary display panel DP-I. The preliminary display panel DP-I may include a base layer BL, a circuit element layer DP-CL, an anode AE, a preliminary sacrificial pattern SP-I, and a pixel-defining film PDL.

The circuit element layer DP-CL may be formed through a typical process for manufacture of a circuit element by forming an insulation layer, a semiconductor layer, and a conductive layer through a method, such as coating or deposition, and then selectively patterning the insulation layer, the semiconductor layer, and the conductive layer through a photolithography process and an etching process to form a semiconductor pattern, a conductive pattern, signal lines, and the like.

The anode AE and the preliminary sacrificial pattern SP-I may be formed through the same patterning process. The pixel-defining film PDL may be located on the base layer BL. The pixel-defining film PDL may cover both the anode AE and the preliminary sacrificial pattern SP-I.

In addition, the method for manufacturing the display panel according to one or more embodiments of the present disclosure may include forming a preliminary partition wall PW-I on the pixel-defining film PDL. The preliminary partition wall PW-I may include a first preliminary partition wall layer L1-I, a preliminary partition wall insulation layer IL-I, and a second preliminary partition wall layer L2-I.

The first preliminary partition wall layer L1-I, the preliminary partition wall insulation layer IL-I, and the second preliminary partition wall layer L2-I may be formed through a process of depositing a conductive material. The first preliminary partition wall layer L1-I may be deposited on the pixel-defining film PDL, the preliminary partition wall insulation layer IL-I may be deposited on the first preliminary partition wall layer L1-I, and the second preliminary partition wall layer L2-I may be deposited on the preliminary partition wall insulation layer IL-I.

Each of the first and second preliminary partition wall layers L1-I and L2-I may include a conductive material. For example, the conductive material may include a metal, a transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), tungsten (W), or an alloy. The transparent conductive oxide may include an indium tin oxide (ITO), an indium zinc oxide (IZO), a zinc oxide, an indium oxide, an indium gallium oxide, an indium gallium zinc oxide (IGZO), or an aluminum zinc oxide. For example, the second preliminary partition wall layer L2-I may include a material having a characteristic of a melting point of about 970 degrees or more. In one or more embodiments, the second preliminary partition wall layer L2-I may include at least one of titanium (Ti), molybdenum (Mo), or tungsten (W). The materials of the first and second preliminary partition wall layers L1-I and L2-I are examples, and are not limited to the foregoing examples.

The preliminary partition wall insulation layer IL-I may include an insulation material. The preliminary partition wall insulation layer IL-I may be located between the first preliminary partition wall layer L1-I and the second preliminary partition wall layer L2-I to block an electrical connection between the first preliminary partition wall layer L1-I and the second preliminary partition wall layer L2-I.

Thereafter, referring to FIG. 7B, the method for manufacturing the display panel according to one or more embodiments of the present disclosure may include forming a first photoresist layer PR1 on the preliminary partition wall PW-I. The first photoresist layer PR1 may be formed by forming a preliminary photoresist layer on the preliminary partition wall PW-I, and by then patterning the preliminary photoresist layer by using a photo mask. A photo opening OP-PR may be formed in the first photoresist layer PR1 through a patterning process. The photo opening OP-PR may overlap the anode AE.

Thereafter, referring to FIGS. 7C and 7D, the method for manufacturing the display panel according to one or more embodiments of the present disclosure may include forming a partition wall PW having a partition wall opening OP-P from the preliminary partition wall PW-I (see FIG. 7B). The forming of the partition wall PW may include first etching of the first preliminary partition wall layer L1-I, the preliminary partition wall insulation layer IL-I, and the second preliminary partition wall layer L2-I, and second etching of the first preliminary partition wall layer L1-I.

First, as illustrated in FIG. 7C, in the first etching of the first preliminary partition wall layer L1-I, of the preliminary partition wall insulation layer IL-I, and of the second preliminary partition wall layer L2-I, the first preliminary partition wall layer L1-I, the preliminary partition wall insulation layer IL-I, and the second preliminary partition wall layer L2-I, may be dry-etched by using the first photoresist layer PR1 as a mask. A portion of the preliminary partition wall PW-I, which does not overlap the first photoresist layer PR1, may be etched to be removed. A preliminary partition wall opening OP-PI may be formed in a portion that overlaps the photo opening OP-PR to be removed.

The first dry etching process may be performed in an etching environment in which etch selectivities of the first preliminary partition wall layer L1-I, the preliminary partition wall insulation layer IL-I, and the second preliminary partition wall layer L2-I are substantially the same. Accordingly, an inner side surface of the first preliminary partition wall layer L1-I, an inner side surface of the preliminary partition wall insulation layer IL-I, and an inner side surface of the second preliminary partition wall layer L2-I, which define the preliminary partition wall opening OP-PI, may be substantially aligned with each other.

Then, as illustrated in FIG. 7D, in the second etching of the first preliminary partition wall layer L1-I (see FIG. 7C), the first preliminary partition wall layer L1-I may be wet-etched by using the first photoresist layer PR1 as a mask. Accordingly, a portion of the first preliminary partition wall layer L1-I may be etched to form the partition wall opening OP-P. The partition wall opening OP-P may be formed to overlap the anode AE.

The partition wall opening OP-P of the partition wall PW may include a first area A1 and a second area A2. The first area A1 may be defined by an inner side surface of a first partition wall layer L1, and the second area A2 may be defined by an inner side surface of a partition wall insulation layer IL and an inner side surface of a second partition wall layer L2. A width of the first area A1 in one direction (e.g., in a direction perpendicular to the third direction DR3, or in plan view) may be greater than a width of the second area A2 in the one direction (e.g., in the direction perpendicular to the third direction DR3, or in plan view).

The second wet etching process in one or more embodiments of the present disclosure may be performed in an etching environment in which a difference in etch selectivity between the first preliminary partition wall layer L1-I (see FIG. 7C), the preliminary partition wall insulation layer IL-I (see FIG. 7C), and the second preliminary partition wall layer L2-I (see FIG. 7C) is relatively great. Accordingly, the inner side surface of the partition wall PW, which defines the partition wall opening OP-P, may have an undercut shape on a cross-section. For example, as the first preliminary partition wall layer L1-I has a higher etch rate for an etchant than an etch rate of each of the preliminary partition wall insulation layer IL-I and the second preliminary partition wall layer L2-I, the first preliminary partition wall layer L1-I may be mainly etched. Accordingly, the inner side surface of the first partition wall layer L1 may be formed to be recessed inwardly from each of the inner side surface of the partition wall insulation layer IL and the inner side surface of the second partition wall layer L2. A tip part may be formed on the partition wall PW by a portion, which protrudes from the first partition wall layer L1, of each of the partition wall insulation layer IL and the second partition wall layer L2.

Thereafter, referring to FIG. 7E, the method for manufacturing the display panel according to one or more embodiments of the present disclosure may include etching the pixel-defining film PDL to form a light-emitting opening OP-E overlapping the partition wall opening OP-P.

In the etching of the pixel-defining film PDL, the pixel-defining film PDL may be dry-etched by using the first photoresist layer PR1 and the partition wall PW (e.g., second partition wall layer L2) as a mask. A portion of the pixel-defining film PDL that does not overlap the first photoresist layer PR1 and the partition wall PW may be etched to be removed. As a result, the light-emitting opening OP-E overlapping to the partition wall opening OP-P may be formed in the pixel-defining film PDL.

Thereafter, referring to FIG. 7F, the method for manufacturing the display panel according to one or more embodiments of the present disclosure may include etching the preliminary sacrificial pattern SP-I (see FIG. 7E) to form a sacrificial pattern SP having a sacrificial opening OP-E overlapping the light-emitting opening OP-E.

In the etching of the preliminary sacrificial pattern SP-1, the preliminary sacrificial pattern SP-I may be wet-etched using, as a mask, the first photoresist layer PR1 and the partition wall PW (e.g., second partition wall layer L2). A portion of the preliminary sacrificial pattern SP-I that does not overlap the first photoresist layer PR1 and the partition wall PW may be etched to be removed. As a result, the sacrificial pattern SP may be formed from the preliminary sacrificial pattern SP-I.

The etching of the sacrificial pattern SP may be performed in an etching environment, in which a difference in etch selectivity between the sacrificial pattern SP and the anode AE is great, and accordingly, the anode AE may not be etched with the sacrificial pattern SP. That is, the sacrificial pattern SP1 having a higher etch rate than the anode AE may be located between the pixel-defining film PDL and the anode AE so that the anode AE is not etched therewith to be damaged during the etching.

Thereafter, referring to FIG. 7G, the method for manufacturing the display panel may include, after removing the first photoresist layer PR1 (see FIG. 7F), forming the light-emitting pattern EP in the light-emitting opening OP-E, and a light-emitting pattern dummy layer D_EP, which may include the same material as the light-emitting pattern EP, on the partition wall PW.

The forming of the light-emitting pattern EP may include a process of depositing a light-emitting layer. For example, the forming of the light-emitting pattern EP may include performing thermal evaporation on the light-emitting layer. The light-emitting layer may be separated by the tip part formed on the partition wall PW to be deposited inside the partition wall opening OP-P and on the partition wall PW. The light-emitting layer formed in the partition wall opening OP-P may form the light-emitting pattern EP, and the light-emitting layer formed on the partition wall PW may form the light-emitting pattern dummy layer D_EP. That is, the light-emitting pattern EP may be formed on the anode AE to overlap the partition wall opening OP-P, and the light-emitting pattern EP may be formed while covering the anode AE and the pixel-defining film PDL.

The light-emitting pattern dummy layer D_EP formed during the forming of the light-emitting pattern EP may include an organic material. For example, the light-emitting pattern dummy layer D_EP may include the same material as the light-emitting pattern EP. The light-emitting pattern dummy layer D_EP may be formed concurrently or substantially simultaneously with the light-emitting pattern EP through one process, and then may be separated from the light-emitting pattern EP due to the undercut shape of the partition wall PW.

Thereafter, referring to FIG. 7H, the method for manufacturing the display panel according to one or more embodiments of the present disclosure may include applying heat to the partition wall PW to remove the light-emitting pattern dummy layer D_EP.

In the applying of the heat to the partition wall PW to remove the light-emitting pattern dummy layer D_EP, a voltage PE may be applied to the second partition wall layer L2 to cause Joule heating. Due to the Joule heating, the light-emitting pattern dummy layer D_EP located on the second partition wall layer L2 may be removed. As the light-emitting pattern dummy layer D_EP includes an organic material, the light-emitting pattern dummy layer D_EP may be evaporated at a temperature of about 250 degrees to about 350 degrees, and the second partition wall layer L2 may not be evaporated as being made of a metal having a high melting point. According to one or more embodiments of the present disclosure, as the process for the light-emitting pattern dummy layer D_EP through Joule heating may suitably use applying only the voltage, the process may be suitably performed.

In the process above, the partition wall insulation layer IL may be located between the first partition wall layer L1 and the second partition wall layer L2 to block an electrical connection between the first partition wall layer L1 and the second partition wall layer L2. That is, when the voltage PE is applied to the second partition wall layer L2, and thus current flows through the second partition wall layer L2, the current flowing to the first partition wall layer L1 may be reduced or prevented. Thus, heat caused by Joule heating may not be transferred to the first partition wall layer L1.

Thereafter, referring to FIG. 7I, the method for manufacturing the display panel may include forming the cathode CE in the light-emitting opening OP-E and the partition wall opening OP-P, and a cathode dummy layer D_CE including the same material as the cathode CE on the partition wall PW.

The forming of the cathode CE may include a process of depositing a cathode layer. For example, the forming of the cathode CE may include sputtering the cathode layer. The cathode layer may be separated by the tip part formed on the partition wall PW to be deposited inside the partition wall opening OP-P and on the partition wall PW. The cathode layer formed in the partition wall opening OP-P may form the cathode CE, and the cathode layer formed on the partition wall PW may form the cathode dummy layer D_CE. That is, the cathode CE may be formed on the light-emitting pattern EP to overlap the partition wall opening OP-P, and the cathode CE may be formed while covering the light-emitting pattern EP. In addition, the cathode CE may be formed to contact the inner side surface of the partition wall PW to extend along the inner side surface of the partition wall PW.

The cathode dummy layer D_CE formed together in the forming of the cathode CE may include a conductive material. For example, the cathode dummy layer D_CE may include the same material as the cathode CE. The cathode dummy layer D_CE may be formed concurrently or substantially simultaneously with the cathode CE through one process, and then may be separated from the cathode CE due to the undercut shape of the partition wall PW. As the light-emitting pattern dummy layer D_EP (see FIG. 7H) is removed in the previous process, the cathode dummy layer D_CE may be located directly on the partition wall PW.

The anode AE, the light-emitting pattern EP, and the cathode CE may be stacked in sequence in the third direction DR3. The anode AE, the light-emitting pattern EP, and the cathode CE may form the light-emitting element ED.

Thereafter, referring to FIGS. 7J and 7K, the method for manufacturing the display panel according to one or more embodiments of the present disclosure may include forming a lower inorganic encapsulation pattern LIL on the cathode CE. The forming of the lower inorganic encapsulation pattern LIL may include depositing a lower inorganic encapsulation layer LIL-I, and removing a portion of the lower inorganic encapsulation layer LIL-I, which does not overlap the light-emitting element ED. The depositing of the lower inorganic encapsulation layer LIL-I will be described with reference to FIG. 7J, and the removing of the portion of the lower inorganic encapsulation layer LIL-I, which does not overlap the light-emitting element ED, will be described with reference to FIG. 7K.

First, referring to FIG. 7J, the forming of the lower inorganic encapsulation pattern LIL may include the depositing of the lower inorganic encapsulation layer LIL-l. In one or more embodiments, the lower inorganic encapsulation layer LIL-I may be formed through a chemical vapor deposition (CVD) process. The lower inorganic encapsulation layer LIL-I may be formed to cover the cathode CE and the partition wall PW.

Then, a second photoresist layer PR2 may be formed on the lower inorganic encapsulation layer LIL-l. In the forming of the second photoresist layer PR2, a preliminary photoresist layer may be formed, and then the preliminary photoresist layer may be patterned using a photo mask to form the second photoresist layer PR2. The second photoresist layer PR2 may be formed, through a patterning process, in the form of a pattern corresponding to the first light-emitting element ED.

Thereafter, referring to FIG. 7K, the forming of the lower inorganic encapsulation pattern LIL may include the removing of the portion of the lower inorganic encapsulation layer LIL-I (see FIG. 7J), which does not overlap the light-emitting element ED.

In the removing of the portion of the lower inorganic encapsulation layer LIL-I, which does not overlap the light-emitting element ED, the lower inorganic encapsulation layer LIL-I may be dry-etched using the second photoresist layer PR2 as a mask. A portion of the lower inorganic encapsulation layer LIL-I that does not overlap the second photoresist layer PR2 may be removed, and a portion of the lower inorganic encapsulation layer LIL-I that is not etched, to thereby remain, may form the lower inorganic encapsulation pattern LIL. A portion of the lower inorganic encapsulation pattern LIL, which is etched and formed, may be formed in the partition wall opening OP-P, and another portion of the lower inorganic encapsulation pattern LIL may be formed on the partition wall PW. The other portion of the lower inorganic encapsulation pattern LIL may be spaced apart from the top surface U_PW (see FIG. 5A) of the partition wall PW on a cross-section.

Then, referring to FIG. 7L, the method for manufacturing the display panel according to one or more embodiments of the present disclosure may include, after removing the second photoresist layer PR2 (see FIG. 7K), removing a portion or the entirety of the cathode dummy layer D_CE, and forming the organic encapsulation film OL and the upper inorganic encapsulation film UIL to complete a display panel DP.

In the removing of the portion or the entirety of the cathode dummy layer D_CE, the cathode dummy layer D_CE may be removed by wet etching. An organic material may be applied through an inkjet process to form the organic encapsulation film OL, but one or more embodiments of the present disclosure is not limited thereto. The organic encapsulation film OL may provide a planarized top surface. Thereafter, an inorganic material may be deposited to form the upper inorganic encapsulation film UIL. Accordingly, the display panel DP, which includes a base layer BL, a circuit element layer DP-CL, a display element layer DP-OLED, and a thin-film encapsulation layer TFE, may be formed.

Forming the partition wall openings OP1-P, OP2-P and OP3-P (see FIG. 6) and the light-emitting openings OP1-E, OP2-E and OP3-E (see FIG. 6), which correspond to light-emitting areas respectively having different colors, in the partition wall PW and the pixel-defining film PDL, forming the light-emitting elements ED1, ED2 and ED3 (see FIG. 6) that respectively provide different colors, and forming the lower inorganic encapsulation patterns LIL1, LIL2 and LIL3 (see FIG. 6) that cover the light-emitting elements ED1, ED2 and ED3 (see FIG. 6) that respectively provide different colors, may be further performed between the forming of the lower inorganic encapsulation pattern LIL and the completing of the display panel DP. The forming of the partition wall openings OP1-P, OP2-P and OP3-P and the light-emitting openings OP1-E, OP2-E and OP3-E, the forming of the light-emitting elements ED1, ED2 and ED3, and the forming of the lower inorganic encapsulation patterns LIL1, LIL2 and LIL3, may be substantially the same as the processes described with reference to FIGS. 7A to 7K. Accordingly, the display panel DP illustrated in FIG. 6 may be formed, which includes the first to third light-emitting elements ED1, ED2 and ED3 that correspond to the plurality of light-emitting areas PXA-R, PXA-G, and PXA-B, and the first to third lower inorganic encapsulation patterns LIL1, LIL2 and LIL3, which correspond to the first to third light-emitting elements ED1, ED2 and ED3, respectively.

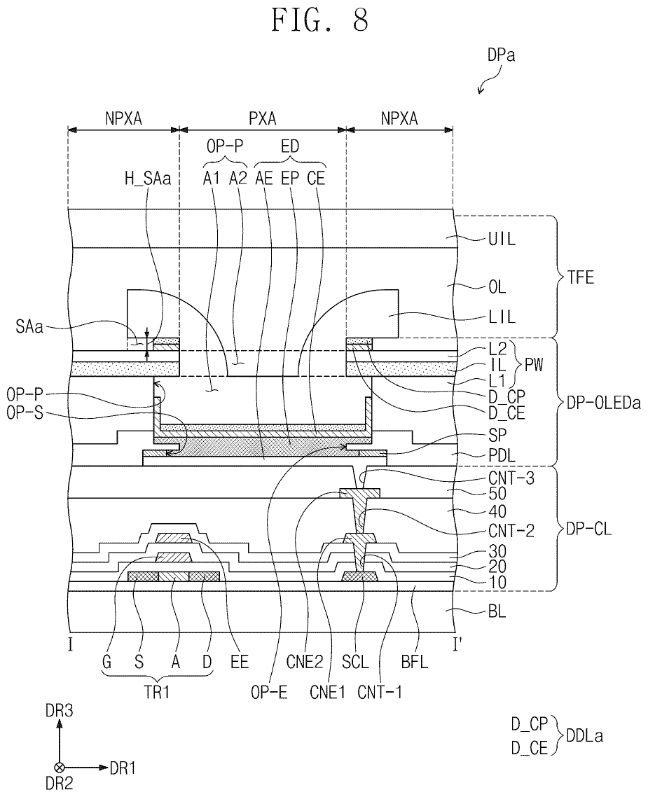

FIG. 8 is a cross-sectional view taken along the line I-I′ in FIG. 3. The cross-sectional view in FIG. 8 corresponds to the cross-sectional view in FIG. 5A, and FIG. 8 illustrates one or more other embodiments of the present disclosure. FIG. 8 will be described by denoting the same/similar components as/to those described with reference to FIGS. 1 to 7L with the same/similar reference numbers or symbols, and by omitting redundant description.

Referring to FIG. 8, a display panel DPa may include a base layer BL, a circuit element layer DP-CL, a display element layer DP-OLEDa, and a thin-film encapsulation layer TFE. The display element layer DP-OLEDa may include a light-emitting element ED, a capping pattern CP, a sacrificial pattern SP, a pixel-defining film PDL, a partition wall PW, and a dummy layer DDLa.

The display element layer DP-OLEDa in FIG. 8 may further include the capping pattern CP compared to the display element layer DP-OLED in FIG. 5A. The capping pattern CP may be located in the partition wall opening OP-P, and may be located on a cathode CE. The capping pattern CP may be patterned by a tip part defined in the partition wall PW.

A portion of a capping pattern layer patterned by the tip part may provide a capping pattern dummy layer D_CP on the partition wall PW. The capping pattern dummy layer D_CP may include the same material as the capping pattern CP, and may be provided on the cathode dummy layer D_CE. The cathode dummy layer D_CE and the capping pattern dummy layer D_CP may provide a dummy layer DDLa.

A separation area SAa may be defined between a lower inorganic encapsulation pattern LIL and the partition wall PW. The dummy layer DDLa may be located in a portion of the separation area SAa. That is, the cathode dummy layer D_CE and the capping pattern dummy layer D_CP may be located in the separation area SAa. A height (e.g., thickness) H_SAa of the separation area SAa may correspond to the sum of a height (e.g., thickness) of the cathode CE and a height (e.g., thickness) of the capping pattern CP. That is, the height H_SAa of the separation area SAa may be substantially the same as a thickness of the dummy layer DDLa provided inside the separation area SAa.

A method for manufacturing a display panel in FIG. 8 may further include, between the operations described with reference to FIGS. 7I and 7J, forming the capping pattern CP in the partition wall opening OP-P, and forming the capping pattern dummy layer D_CP, which includes the same material as the capping pattern CP, on the partition wall PW.

FIG. 8 illustrates an example in which the dummy layer DDLa is located in the separation area SAa. However, the separation area SAa may be empty in one or more other embodiments. In this case, the entirety of the dummy layer DDLa may be removed by wet etching.

As described above, the separation area may be defined between the lower inorganic encapsulation pattern and the partition wall. The height of the separation area may correspond to the height of the cathode, and the height of the separation area may be relatively small. As the height of the separation area is remarkably less than the deposition thickness (about 2000 angstrom to about 3000 angstrom) of the light-emitting pattern, the subsequent light-emitting pattern may not be located in the separation area. Thus, in the manufacture of the display panel, the over-etching of the lower inorganic encapsulation pattern may be reduced or removed, and the display panel defect due to the water vapor transmission may be improved.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the technical scope of the present disclosure is not limited to the contents described in the detailed description of the specification, but should be determined by the claims, with functional equivalents thereof to be included therein.

What is claimed is:

1. A display panel comprising:
a base layer;
a pixel-defining film above the base layer, and defining a light-emitting opening;
a partition wall above the pixel-defining film, defining a partition wall opening corresponding to the light-emitting opening, and comprising:
a first partition wall layer comprising a first conductive material;
a partition wall insulation layer above the first partition wall layer, and comprising an insulation material; and
a second partition wall layer above the partition wall insulation layer, and comprising a second conductive material; and
a light-emitting element in the light-emitting opening and the partition wall opening, and comprising an anode, a light-emitting pattern, and a cathode, the cathode contacting the partition wall.

2. The display panel of claim 1, wherein the partition wall opening comprises:
a first area defined by an inner side surface of the first partition wall layer; and
a second area defined by an inner side surface of the partition wall insulation layer, and an inner side surface of the second partition wall layer,
wherein a width of the first area in one direction is greater than a width of the second area in the one direction.

3. The display panel of claim 1, further comprising a lower inorganic encapsulation pattern covering the light-emitting element, and spaced apart from a top surface of the partition wall.

4. The display panel of claim 3, wherein a separation area is defined between the lower inorganic encapsulation pattern and the partition wall, and
wherein a thickness of the separation area is substantially equal to a thickness of the cathode.

5. The display panel of claim 4, further comprising a cathode dummy layer in a portion of the separation area, and comprising a same material as the cathode.

6. The display panel of claim 4, wherein the separation area is empty.

7. The display panel of claim 4, wherein the thickness of the separation area is about 200 angstrom (Å) or less.

8. The display panel of claim 4, further comprising a capping pattern above the cathode,
wherein the thickness of the separation area corresponds to a sum of the thickness of the cathode and a thickness of the capping pattern.

9. The display panel of claim 1, wherein the second partition wall layer comprises at least one of titanium (Ti), molybdenum (Mo), or tungsten (W).

10. The display panel of claim 1, wherein the second partition wall layer comprises a material having a melting point of about 970 degrees or more.

11. A method for manufacturing a display panel, the method comprising:
providing a preliminary display panel comprising a base layer, and a pixel-defining film above the base layer;
forming, on the pixel-defining film, a preliminary partition wall comprising:
a first preliminary partition wall layer comprising a first conductive material;
a preliminary partition wall insulation layer comprising an insulation material; and
a second preliminary partition wall layer comprising a second conductive material;
forming a partition wall defining a partition wall opening from the preliminary partition wall;
etching the pixel-defining film to form a light-emitting opening overlapping the partition wall opening;
forming a light-emitting pattern in the light-emitting opening, and forming a light-emitting pattern dummy layer including a same material as the light-emitting pattern, on the partition wall; and
applying heat to the partition wall to remove the light-emitting pattern dummy layer.

12. The method of claim 11, wherein the partition wall comprises:
a first partition wall layer comprising the first conductive material;
a partition wall insulation layer above the first partition wall layer, and comprising the insulation material; and
a second partition wall layer above the partition wall insulation layer, and comprising the second conductive material.

13. The method of claim 12, wherein the forming of the partition wall defining the partition wall opening from the preliminary partition wall comprises:
first etching of the first preliminary partition wall layer, the preliminary partition wall insulation layer, and the second preliminary partition wall layer; and
second etching of the first preliminary partition wall layer.

14. The method of claim 12, wherein the partition wall opening comprises:
a first area defined by an inner side surface of the first partition wall layer; and
a second area defined by an inner side surface of the partition wall insulation layer, and by an inner side surface of the second partition wall layer,
wherein a width of the first area in one direction is greater than a width of the second area in the one direction.

15. The method of claim 12, wherein the applying of the heat to remove the light-emitting pattern dummy layer comprises applying a voltage to the second partition wall layer to cause Joule heating.

16. The method of claim 11, further comprising:
forming a cathode in the light-emitting opening and the partition wall opening; and
forming a cathode dummy layer, which comprises the same material as the cathode, on the partition wall.

17. The method of claim 16, further comprising forming a lower inorganic encapsulation pattern on the cathode,
wherein the cathode dummy layer is between the partition wall and the lower inorganic encapsulation pattern.

18. The method of claim 16, further comprising removing at least a portion of the cathode dummy layer.

19. The method of claim 16, further comprising:
forming a capping pattern in the partition wall opening; and
forming a capping pattern dummy layer, which comprises the same material as the capping pattern, on the partition wall.

20. The method of claim 11, wherein the forming of the preliminary partition wall comprises depositing a second preliminary partition wall layer comprising a material having a characteristic of a melting point of about 970 degrees or more.
